(19) United States
(12) Patent Application Publication
(10) Pub. No.: US 2024/0403507 A1
(43) Pub. Date: Dec. 5, 2024

(54) Suspension System

(71) Applicant: XTravel Suspension, LLC, Southlake, TX (US)

(72) Inventor: Nestor Alexander Berardi, Temecula, CA (US)

(73) Assignee: XTravel Suspension, LLC, Southlake, TX (US)

(21) Appl. No.: 18/735,141

(22) Filed: Jun. 5, 2024

Related U.S. Application Data
(60) Provisional application No. 63/506,243, filed on Jun. 5, 2023.

(51) Int. Cl. G06F 30/15; B60G 3/20

(52) U.S. Cl. CPC G06F 30/15; B60G 3/20; B60G 2200/144; B60G 2200/18; B60G 2204/62; B60G 2600/21; B60G 2800/24

(57) ABSTRACT

Methods for configuring a suspension system for a vehicle are disclosed such that the suspension system has zero scrub radius and zero bump steer. The method details the specific steps required to achieve these goals.

This application claims priority to U.S. provisional patent application No. 63/506,243 filed on Jun. 5, 2023. This and all other referenced extrinsic materials are incorporated herein by reference in their entirety. Where a definition or use of a term in a reference that is incorporated by reference is inconsistent or contrary to the definition of that term provided herein, the definition of that term provided herein is deemed to be controlling.

### FIELD OF THE INVENTION

The field of the invention is suspension systems for vehicles, and specifically, off road vehicles with extensive suspension travel.

### BACKGROUND

The following description includes information that may be useful in understanding the present invention. It is not an admission that any of the information provided herein is prior art or relevant to the presently claimed invention, or that any publication specifically or implicitly referenced is prior art.

While prior art inventions exist that utilize four link or multi-link vehicle suspensions, those known to Applicant all fail to disclose suspension systems and methods to configured such systems to permit a zero bump steer, non-changing initial castor, and constant scrub radius suspension system that permits high travel and utilizes the unique features of the inventive subject matter described below.

One example of a multi-link suspension system is described in U.S. Pat. No. 4,819,959, which discusses multiple different suspension systems. The disclosed suspension systems are designed to have camber gain during steering for the outside wheel in a turn.

U.S. Pat. No. 4,863,188 also discloses a suspension system, which is designed such that during steering, castor (or trail) forces that cause steering to return to center are cancelled out from the inside steered wheel to the outside steered wheel on the opposite side. However, such force balancing is complicated and rendered unnecessary by the inventive subject matter disclosed herein.

As another example, U.S. Pat. No. 9,561,818 discusses a suspension apparatus for a steered wheel having a multi-link suspension. However, the suspension design will gain in track width while being steered, which is undesirable. Yet another example of a multi-link suspension system is described in U.S. Pat. No. 9,216,624 which discloses the multi-link suspension system where the steered wheel hub rotates about two separate instant centers, the “ride axis” from the upper and lower front links and a “handling axis” from the upper and lower rear links. However, like the above patents, this patent also fails to contemplate how to configure the suspension system to minimize bump steer, or unwanted movements in the steered wheels resulting from vertical suspension travel.

United Kingdom Patent No. 1,285,047 also describes multi-link suspension systems. However, this patent also fails to disclose the novel and inventive matter discussed herein, such as how to limit bump steer and reduce steering feedback from external forces. Indeed, while this patent lists a number of configurations of four-link suspension systems, it fails to disclose how and why someone would pick one system over the other, or in fact how to build any of the systems disclosed to achieve a certain outcome.

All publications identified herein are incorporated by reference to the same extent as if each individual publication or patent application were specifically and individually indicated to be incorporated by reference. Where a definition or use of a term in an incorporated reference is inconsistent or contrary to the definition of that term provided herein, the definition of that term provided herein applies and the definition of that term in the reference does not apply.

Thus, there is still a need for suspensions systems and methods for configuring suspension systems to limit bump steer and reduce steering feedback from external forces.

### SUMMARY OF THE INVENTION

The inventive subject matter provides apparatus, systems, and methods for suspension systems for vehicles. Vehicles could include, for example, model or remote-controlled vehicles such as radio-controlled cars, trucks or other vehicles, autonomous vehicles, or passenger vehicles such as automobiles, trucks, all-terrain vehicles, military or fleet vehicles, and snowmobiles.

Contemplated vehicles comprise a chassis to which a suspension system can be coupled. Exemplary suspension systems are described in U.S. patent application having Ser. No. 17/144,654, filed on Jan. 8, 2021 (now U.S. Pat. No. 11,192,414) and U.S. patent application having Ser. No. 17/499,778 filed on Oct. 12, 2021, and are briefly described below. Such systems preferably comprise a multi-link suspension system, where each of the links can move independently or in concert/harmony with each of the other links. However, in other contemplated multi-link suspension systems, one or more of the links may move together with another of the links, such as an A-arm where the links are connected, for example. Still, in other embodiments, it is contemplated that any number of the links of the multi-link suspension system may move in concert with one another.

Contemplated systems and methods described herein provide for a multi-link suspension having constant trail and constant (or zero) scrub radius with a fifth aligning link (steered or fixed) with zero bump steer. This is accomplished by using a three-position graphical synthesis from a two-dimensional front view plane and a three position graphical synthesis on at least one overhead plane subsequently combined and projected to a three-dimensional design, resulting in a conical surface projection of the Kingpin Axis to the tire contact patch center point. Put another way, a high travel suspension system with zero bump steer and non-changing initial castor can be created by analyzing multiple editions of a three position analytical synthesis of four bar linkages with extended end effectors, solved simultaneously in a front pane that is semi-orthogonal to the at least one and preferably two distinct semi parallel planes that are mostly parallel to the horizontal plane, where the front plane is mostly parallel to the vertical transverse plane. If both overhead view planes were parallel to the horizontal plane, the suspension system would exhibit zero anti-dive or anti-squat in the side view. So, the term semi-parallel is needed to denote a plane that is most likely within 20 degrees of parallel to the horizontal plane, and more likely within 7 degrees, all when seen in the side view.

As used herein, the term “constant” is defined to mean within 2 cm of distance or within 7.0%, more preferably within 5.0%, of a distance between the inboard pickup points, and within 3.5%, more preferably within 2.5%, of the initial spindle line, so if the mechanical trail is constant, this means its lengths stays within 2 cm of an initial length or within 7.0% of the initial length.

As used herein, the term “Initial Spindle Axis” refers to a hypothetical line connecting the center of the left and right steered wheels of a vehicle when the vehicle is at rest with the suspension at ride height and the wheels pointed straight ahead. In other words, the wheel centers lie on and define the Initial Spindle Axis, which is set by the wheel and tire size at ride height, the trackwidth, and contributes to the wheelbase by setting the front to rear axle position.

The term “Kingpin Axis” refers to a hypothetical line which creates the initial axis about which the steered wheels rotate during steering of the vehicle for a given vertical suspension position and may also be referred to as the “swivel axis”. If the Kingpin Axis is designed to move during suspension travel, there are multiple “instant” Kingpin Axis' which exist in the system, but only one which exists at any given instant. The term “Initial Castor” means the angle between a line to the ground from the wheel center and the center of the tire contact patch with the ground and the Kingpin Axis. The term “Castor” means the angle in the side view while the term “Mechanical Trail” means the distance between the Kingpin Axis point through the ground plane and the center of the tire contact patch on the ground.

The term “Scrub Radius” refers to the distance in front view between the Kingpin Axis and the center of the tire contact patch, where both would theoretically touch the ground. As discussed herein, “Bump Steer” refers to situations where the wheels of the vehicle steer themselves without input from the steering wheel or operator, usually due to vertical suspension travel, but also originating from compliance in the suspension system. This can occur due to the wheel encountering bumps, objects, or hazards on the road when the vehicle is moving and is of particular importance for off-road driving.

It is contemplated that the steered suspension geometry may be configured such that a line through an idealized virtual pivot point formed by an extension of the upper and lower suspension links extends to the ground in such a way that any transverse or longitudinal movement of the tire contact patch is designed to be zero across the commonly used range of steering angles and commonly used suspension travel in bump and droop.

The inventive subject matter described herein allows for a multi-link vehicle suspension system for steered wheels with zero scrub radius and zero bump steer by utilizing a three-position analytical synthesis of four links with extended end-effectors, solved simultaneously in two semi-orthogonal planes for frontal and overhead constraints of three-dimensional links forming the vehicle's suspension. An integral part of this range of vertical suspension travel is allowing the wheel to gain or lose camber during vertical travel while the track width stays the same, exhibiting an effect of zero scrub radius for the steered wheels. As a result, the distance from one tire to another tire, on the ground, at the center of the contact patch, will remain constant (in track and wheel base) because changes in camber are allowed.

In contrast to suspensions of the prior art where camber gain in roll is related to the set value of castor and potentially other factors, the inventive subject matter described herein allows both camber and castor to be optimized separately. This advantageously allows for varying of the roll center to dictate how much camber gain results from body roll or vertical suspension travel.

As discussed below, the point where the steering axis of the wheel passes through the tire contact patch does not change based on steering input or suspension travel. In other words, steering input and suspension travel will produce zero feedback through the steering mechanism. In such embodiments, it is desired that static Kingpin Axis Angle and initial Castor Angle are non-zero, but will not change in value during or suspension travel.

In embodiments where the front upper and lower inboard pick up points on the vehicle's chassis do not form a horizontal lie as seen from the side (such as to exhibit anti-dive or anti squat with conventional A-Arm geometry), the plane drawing through the inboard suspension pick up points will be reclined slightly rearward from the vertical transverse plane, while remaining perpendicular to the vertical longitudinal plane. All the same steps as described herein can be followed after that slight change to the creation of the initial upper and/or lower inboard pick up plane.

While many of the embodiments discussed herein disclose a double upper and lower ball joint set for the articulating suspension system, one skilled in the art could utilize the disclosed subject matter discussed herein to create a suspension system with a single outboard ball joint at either the upper or lower suspension link set and continue to use the inventive concepts discussed herein. The geometric decoupling of the longitudinal forces (FIG. 1a, X) from the transverse forces (FIG. 1a, Y) has also shown improvements in operator comfort and fatigue. While the described systems and methods are most advantageously used to eliminate feedback in high-travel off road vehicles, the systems and methods discussed herein can be adjusted to allow for partial feedback, to the operator, for example as may be desired by a road racing vehicle operator who requires feedback to feel the road surface and anticipate handling corrections.

Various objects, features, aspects and advantages of the inventive subject matter will become more apparent from the following detailed description of preferred embodiments, along with the accompanying drawing figures in which like numerals represent like components.

### BRIEF DESCRIPTION OF THE DRAWINGS

FIG. 1a illustrates definitions of various planes and directions with respect to a vehicle.

FIG. 1b illustrates a schematic of a wheel and definitions for various terms used herein.

FIG. 2a-2c illustrate various views of one embodiment of a chassis of a vehicle.

FIG. 3 illustrates a location of the center of the tire contact patch on the ground, which defines the ride-height of the chassis, the trackwidth, and is an input to the wheelbase of the vehicle.

FIG. 4 illustrates a front construction plane (named the FrontUpLow Suspension plane) with a ground plane defined by a chassis ride height and a Spindle Axis defined by a tire fore/aft location and height above ground.

FIGS. 5a-5b illustrates various views of a vehicle's chassis with a wheel.

FIG. 6a illustrates a front view of one embodiment of a suspension system at ride height.

FIG. 6b illustrates a three position synthesis and constrained track width during vertical suspension travel of the suspension system shown in FIG. 6a.

FIG. 6c illustrates exemplary dependent and independent variables and measurements for suspension component lengths of the suspension system shown in FIG. 6a.

FIG. 7 illustrates an isometric view of the two-dimensional sketches of FIGS. 6a-6c.

FIG. 8a illustrates an isometric view with upper, lower, and initial Spindle Axis projections out to the Kingpin Axis, and some Static Castor detailed by a non-zero Mechanical Trail.

FIGS. 8b-8h illustrates the overhead and isometric views of the two-dimensional sketches of upper, then lower, suspensions links drawn on the planes of the Upper and Lower Spindle Axis, in single or multiple steering positions.

FIG. 9 illustrates a two-dimensional front view of another embodiment of a suspension system at three positions with ride height (center) position projected back as two-dimensional drawing to plane of Spindle Axis (tire center axis).

FIG. 10 illustrates a three-dimensional isometric view of the two-dimensional front view shown in FIG. 9.

FIG. 11 illustrates an isometric view of the three-dimensional synthesis of a suspension system combined with at least one of the two-dimensional overhead views from 8b the frontal view of the center position, or ride height, view from FIG. 10.

FIGS. 12a-12d illustrate various three-dimensional views of a suspension system.

FIGS. 13a-13c illustrate two-dimensional views illustrating movement of the suspension system during vertical suspension travel with the steering linkage added in at multiple positions.

FIGS. 14a-14c illustrate three-dimensional renderings of a suspension system.

FIGS. 15a-15c illustrate various instant Kingpin Axis lines through a sweep of steering at multiple angles for a given vertical suspension position.

FIGS. 16a-16c illustrate three-dimensional renderings of the vehicle corner in three dimensions showing movement of the tire.

FIGS. 17a-17d illustrate additional three-dimensional renderings of the vehicle corner shown in FIGS. 16a-16c.

### DETAILED DESCRIPTION

The following discussion provides many example embodiments of the inventive subject matter. Although each embodiment represents a single combination of inventive elements, the inventive subject matter is considered to include all possible combinations of the disclosed elements. Thus, if one embodiment comprises elements A, B, and C, and a second embodiment comprises elements B and D, then the inventive subject matter is also considered to include other remaining combinations of A, B, C, or D, even if not explicitly disclosed.

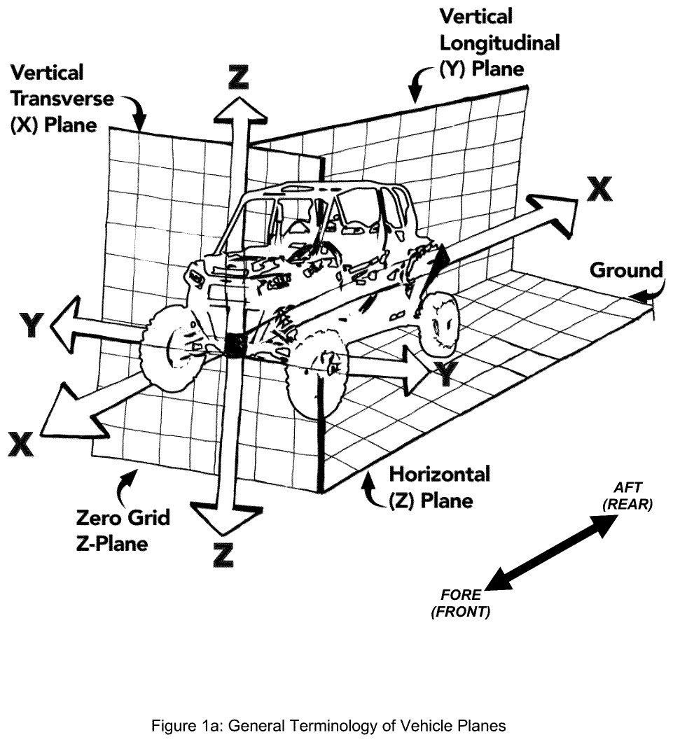

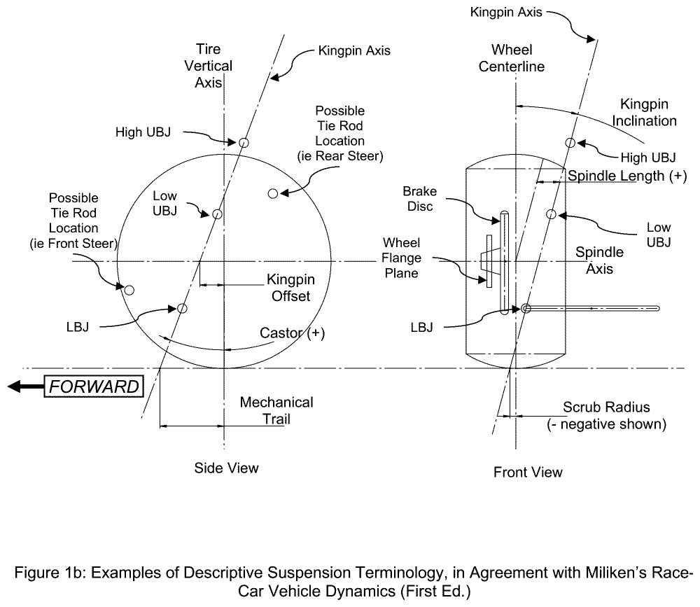

FIG. 1a illustrates vertical transverse, vertical longitudinal, and horizontal planes as used relative to a vehicle. Specifically, FIG. 1a illustrates the three planes of an overland vehicle chassis, the vertical transverse plane (as would create a front view), the vertical longitudinal plane (as would create a side view), and the horizontal plane parallel to the ground. The zero grid Z plane is a vertical transverse plane (front plane) which intersects the front-most portion of the chassis.

FIG. 1b illustrates a schematic of front and side views of a wheel and definitions for various terms used herein. Specifically, the definition of a mechanical trail and scrub radius are shown, along with the Kingpin Axis. In a conventional A-Arm design, the Kingpin Axis intersects the upper ball joint (either a High UBJ or a Low UBJ) and the lower ball joint (LBJ). The mechanical trail is the distance from where the tire or wheel contacts the ground (tire contact patch) and the point where the Kingpin Axis contacts the ground in the side view. The scrub radius is the distance from where the tire or wheel contacts the ground (tire contact patch) and the point where the Kingpin Axis passes through the ground as viewed from the front.

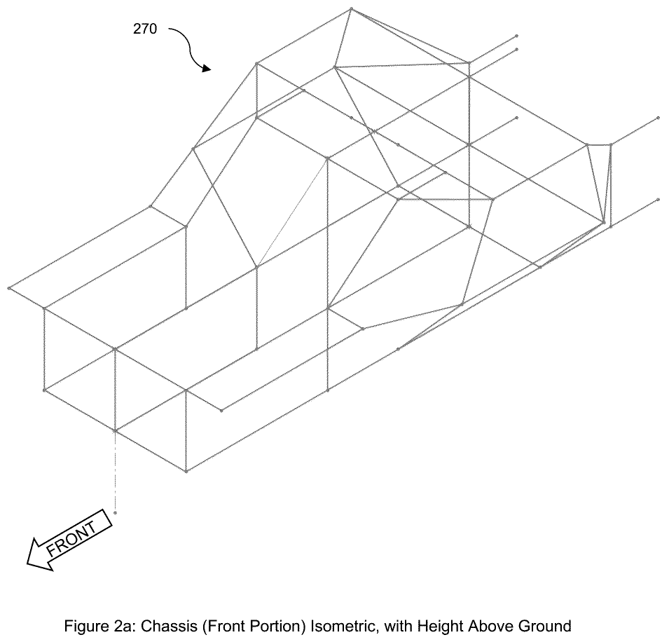

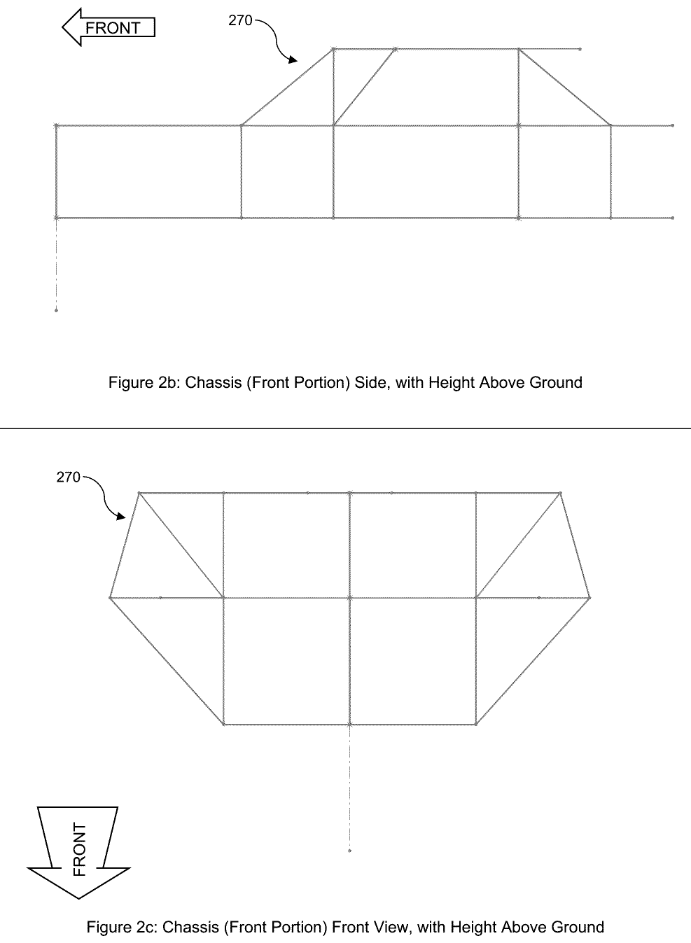

FIGS. 2a-2c illustrate various views of an exemplary chassis 270 of a vehicle. The front, left corner of the vehicle will be used in the following examples and discussion, but the same can be applied to the other portions of the vehicle (e.g., front, right corner and rear left and/or right) where suspension links will couple a wheel to the chassis. As shown in FIG. 2a, the dashed line represents the ride height, or distance from the ground to the front lowest section of the chassis, in a Zero Grid Plane at the vehicle front, when the vehicle and chassis 270 are at rest.

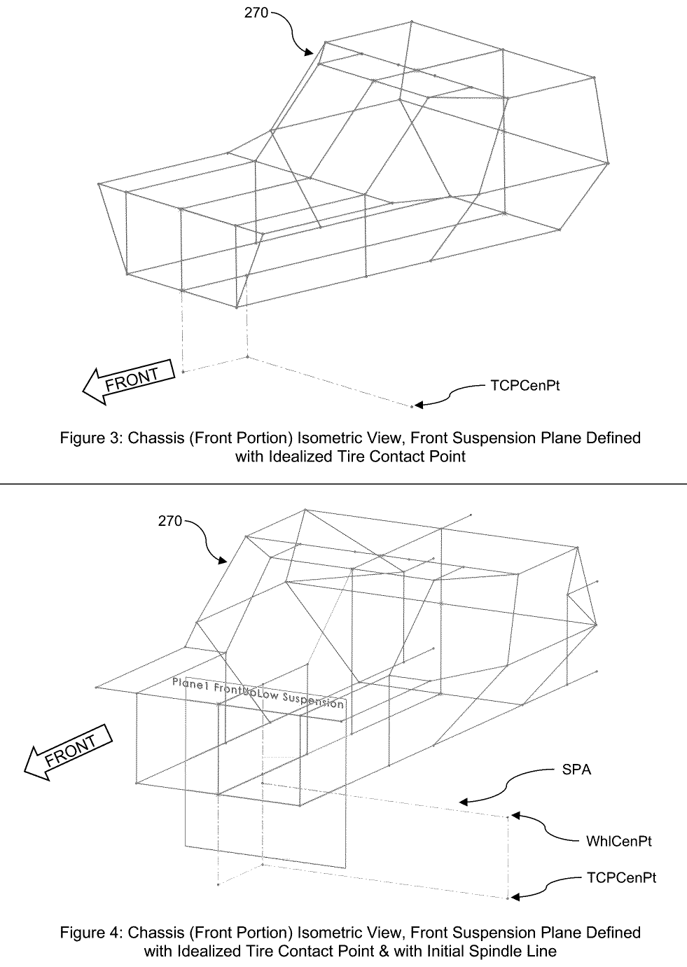

FIG. 3 illustrates the chassis 270 shown in FIGS. 2a-2c with a dashed line drawn from the tire contact patch center point (TCPCenTPt) to a point on the ground below a center of the chassis 270, and thereby denotes half of the vehicle track width.

FIG. 4 illustrates a front construction plane (the FrontUpLow Suspension plane) of the chassis 270, which is perpendicular to the Vertical Longitudinal plane (chassis center plane) and passes through both of the inboard front suspension pickup points, parallel to the Spindle Axis (SPA). The ground plane is defined by a chassis ride height. The Spindle Axis (SPA), or axis of rotation of the tire, is defined by a tire location and height of the wheel center above ground, and is perpendicular to the Vertical longitudinal plane, vertically above the center of the contact patch. Thus, the Spindle Axis is the hypothetical line beginning from a center point of the wheel (WhlCenPt) and extending to the chassis 270.

As can be seen from FIG. 4, the track width of the vehicle is defined as well as the radius (times two for height) and width of the wheel, which may or may not be constrained based on the vehicle. FIG. 4 also illustrates the vehicle ride height. With those values determined or provided, the initial Spindle Axis (SPA) can be determined from the center point of the wheel (WhlCenPt) to the vehicle's centerline.

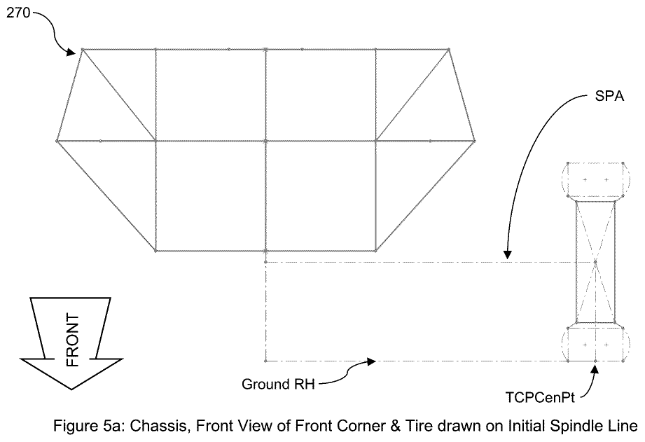

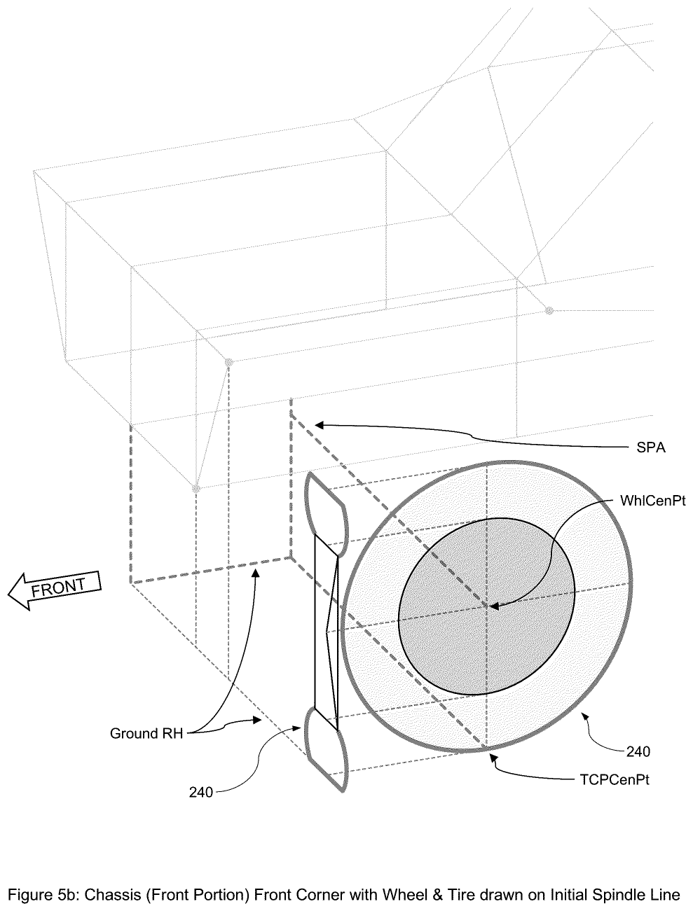

FIG. 5a illustrates a front view of the chassis 270 of FIG. 4 showing an exemplary wheel (tire and rim) as well as the Initial Spindle Axis (SPA) and the Ground Ride Height (Ground RH). As shown in FIGS. 5b-5b, the tire contact patch is where the tire contacts the dashed line representing the ground plane at ride-height (Ground RH), with the tire contact patch center point (TCPCenPt) at the center of the tire width and on the plane of the ground. The tire includes a contact patch with a center point being the point where the tire center axis (TCA) contacts the ground plane. The tire center axis is drawn through the center of the tire. The depicted corner of the suspension assembly may also include a hard rim where the pliable tire mounts, with the rim and the tire referred to throughout collectively as the wheel.

FIG. 5b illustrates an isometric view of FIG. 5a. In FIG. 5b, additional steps of a method for configuring a suspension system are shown, including (i) drawing a point coincident with the tire ground contact center point on the FrontUpLow suspension plane; (ii) drawing a wheel and tire on that plane as defined by previously determined values; and (iii) drawing a spindle/hub/upright line and wheel center point on that plane to define an initial position of those locations. In FIGS. 4, 5a and 5b, the second step of the method can be seen with the initial Spindle Axis (SPA) drawn from the center of the wheel at ride height to the centerline of the chassis 270.

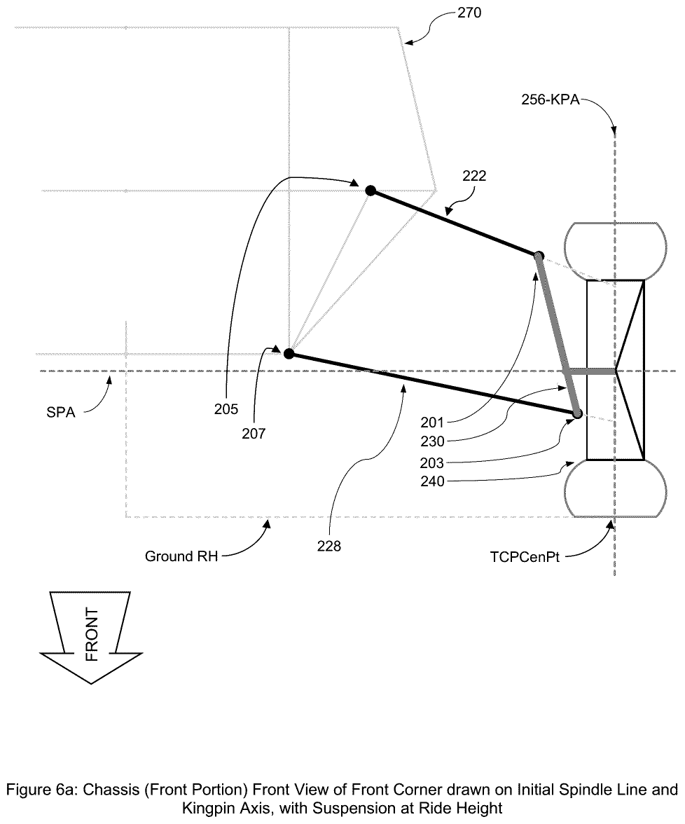

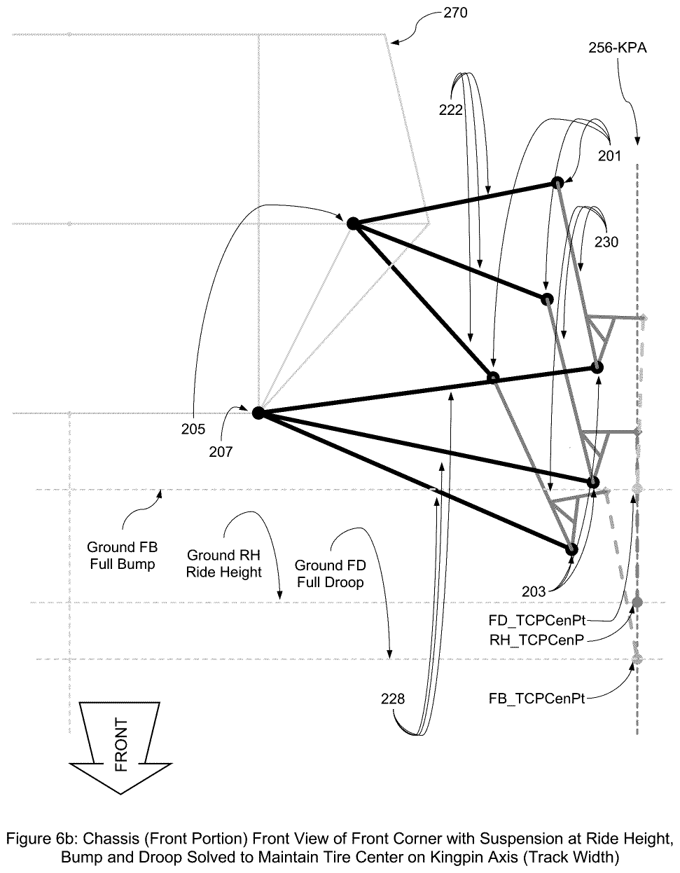

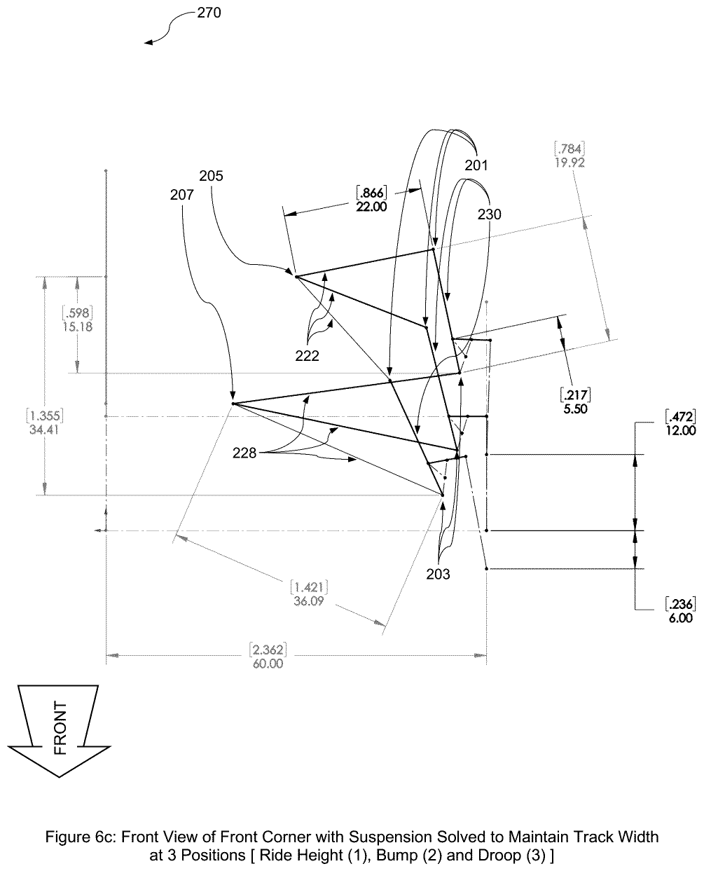

FIGS. 6a-6c illustrate a front portion of the chassis 270 and a close-up depiction of an exemplary two-dimensional view of a front suspension shown at rest with the ride height position drawn on the FrontUpLow Suspension Plane. As shown, the suspension system includes a front, upper link 222 and a front, lower link 228. The front, upper link 222 is coupled to the chassis 270 at point 205 and is coupled to the knuckle 230 at point 201. The front, lower link 228 is coupled to the chassis 270 at point 207 and is coupled to the knuckle 230 at point 203.

Those items are drawn on top of the front view of the Initial Spindle Axis (SPA). FIG. 6a also shows the center of the wheel 240 at the tip of the spindle, and the ground plane at Ride Height (Ground RH), which is shown intersecting the tire at the tire contact patch center point (TCPCenPt). The Kingpin Axis 256 is also shown which here intersects with the tire contact patch center point (TCPCenPt). Initial front view centerline positions of the upper 222 and lower 228 suspension arms are then drawn, most likely chosen to be at ride height when the vehicle is at rest.

FIG. 6b illustrates two more positions of the vehicle's suspension on the same plane for use in a graphical multi-link synthesis, which are generally chosen to be the maximum travel positions of the wheel, namely full bump and full droop, depicted with the chassis in a single position and the horizontal ground plane moved vertically. The three positions of the suspension are shown as Ride Height (Ground RH), a maximum upper travel (Full Bump—Ground FB) and a maximum lower travel (Full Droop—Ground FD). The Kingpin Axis (KPA) 256, about which the tire pivots during steering, is shown as a dashed line connecting the instant centers of the upper link 222 and the lower link 228. The ground plane intersects the tire contact patch center point (TCPCenPt) perpendicular to the tire center axis, in this example without initial camber. The tire contact patch center point (TCPCenPt) is the point where the tire center axis and the outer surface (or tread) of the tire meet the ground plane, intended to depict the road or ground during vehicle operation.

As the wheel travels from full bump to full droop, the track width of the suspension remains constant. In other words, the suspension is geometrically constrained in the three positions as a length of the upper link 222, a length of the lower link 228 and a length of the upright remains constant. In addition, a hypothetical line from the spindle center (to ground) has the same length from the vehicle's centerline. Each of the points where the wheel contacts the ground or other surface at full droop, ride height, and full bump are constrained to be the same distance from a centerline of the chassis 270. Roll Analysis, where one wheel is in full bump and the other is in full droop, is obviously similar, but made even easier with this design where the track width never changes, and the chassis and suspension system can be viewed (from the front) as a parallelogram when the chassis is in roll.

FIG. 6c illustrates one example of specific dimensions for the suspension system shown in FIGS. 6a-6b. The bolded dimensions represent independent variables, which can be adjusted to meet requirements of the operator or other constraints (such as packaging within the wheel and tire combo or brake caliper and rotor clearance), while the non-bolded dimensions represent dependent variables that are fixed and cannot be adjusted.

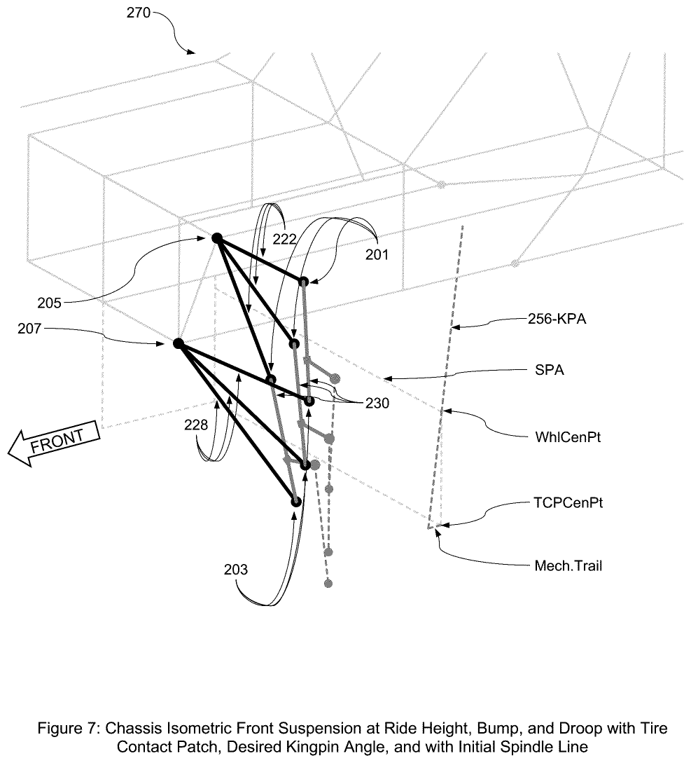

FIG. 7 illustrates an isometric view of the two-dimensional schematics shown in FIGS. 6a-6c drawn on the FrontUpLowPlane. The Spindle Axis (SPA) is also shown. The Kingpin Axis 256 about which the vehicle is steered and the tire contact patch center point (TCPCenPt) are spaced apart from each other to define both a non-zero mechanical trail and a non-zero initial castor where the Kingpin Axis 256 (or steer axis) intersects the ground plane. Thus, the Kingpin Axis 256 (or steer axis) can be placed close to the tire center axis (TCA) to minimize forces within the suspension links due to tractive forces and vertical forces. A length of the scrub radius can be adjusted to influence vehicle handling, as desired. The Kingpin Axis 256 (or steer axis) intersects the ground plane, and the scrub radius is identified as being drawn between the contact patch center point (TCPCenPt) and the Kingpin Axis 256 passing through the ground plane. The Kingpin Axis 256 can be illustrated in three dimensions, through the initial Spindle Axis (SPA), with two chosen angles to the horizontal plane to exhibit initial camber and castor, if desired. Drawing the Mechanical Trail line from the intersection of the ground plane and the Kingpin Axis 256, to the tire ground contact center point in this design where scrub radius is initially zero.

As shown in FIG. 7, the Kingpin Axis 256 intersects the spindle's center, also known as zero kingpin offset as seen in the side plane. It is contemplated that one of ordinary skill in the art could retain the same kingpin angle and incorporate kingpin offset, with the kingpin either in front of the wheel center (positive kingpin offset) or behind the wheel center (negative kingpin offset). This could be done to influence steering characteristics while maintaining the other advantages of the inventive concepts discussed herein.

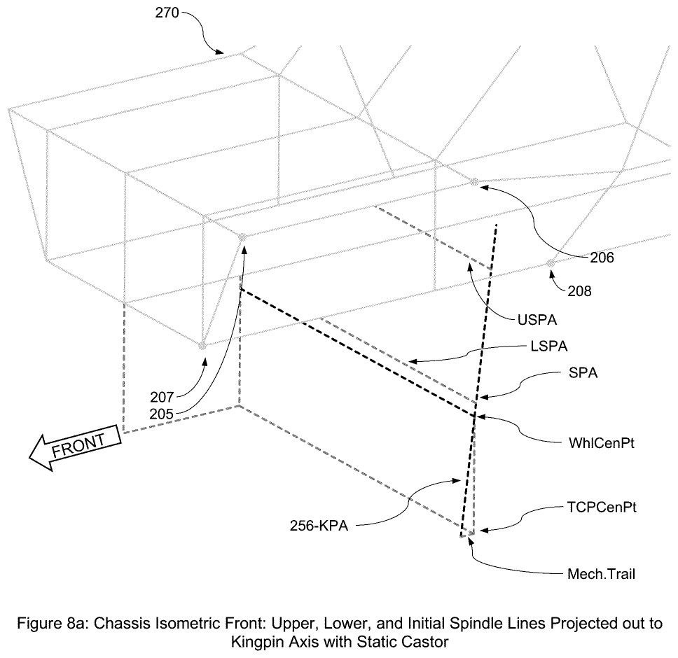

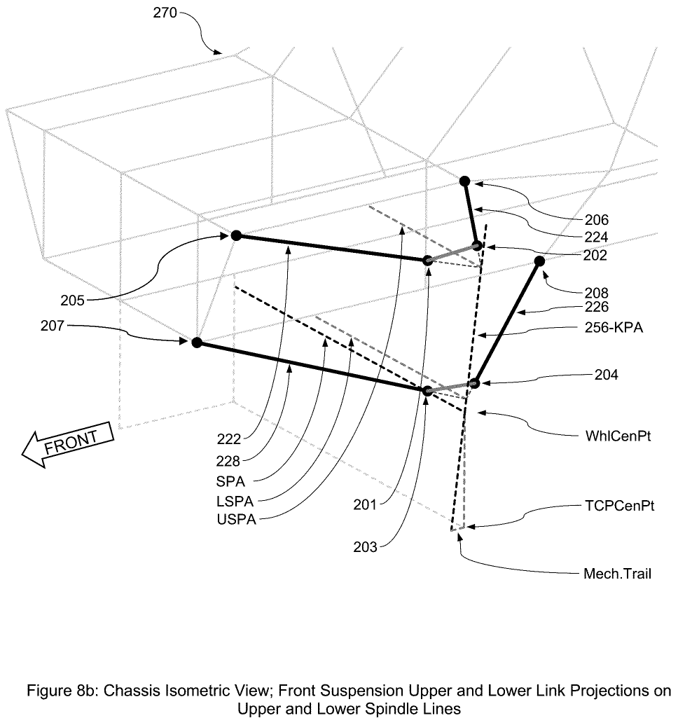

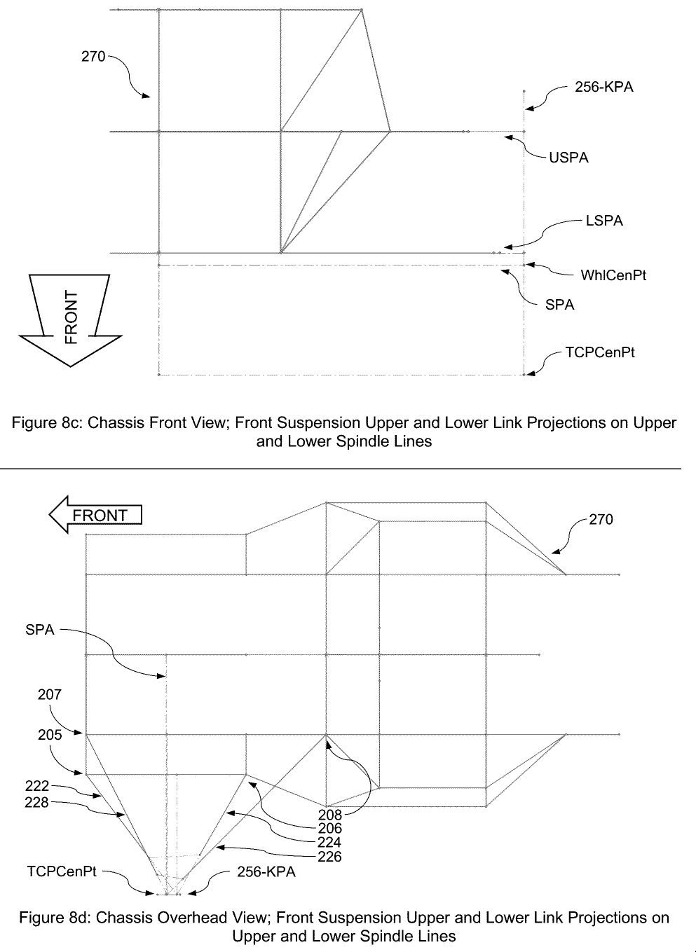

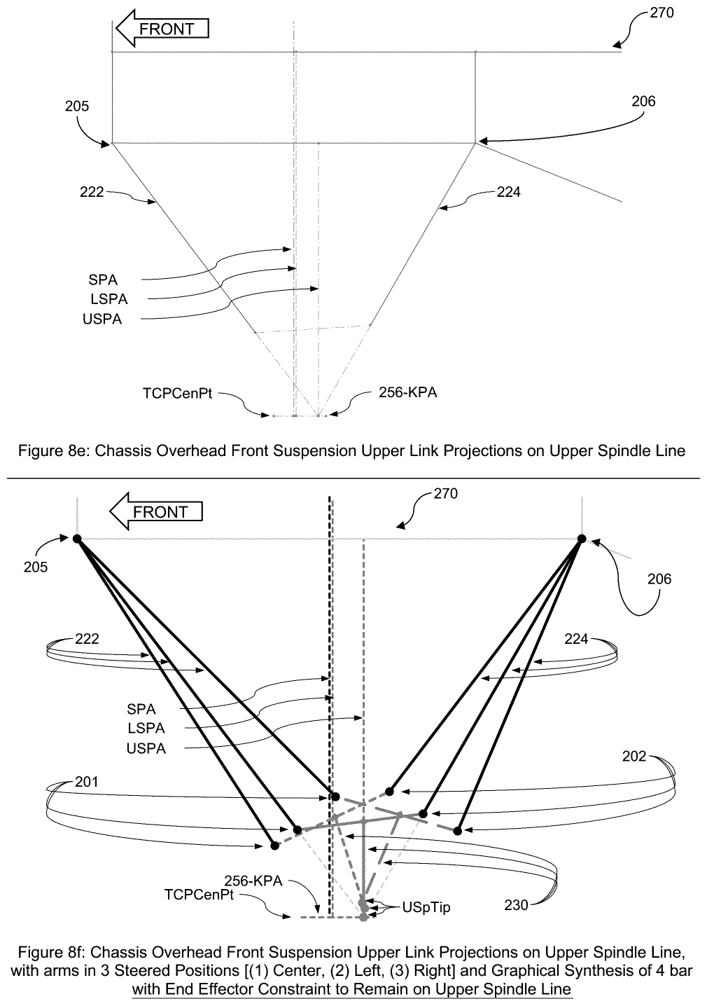

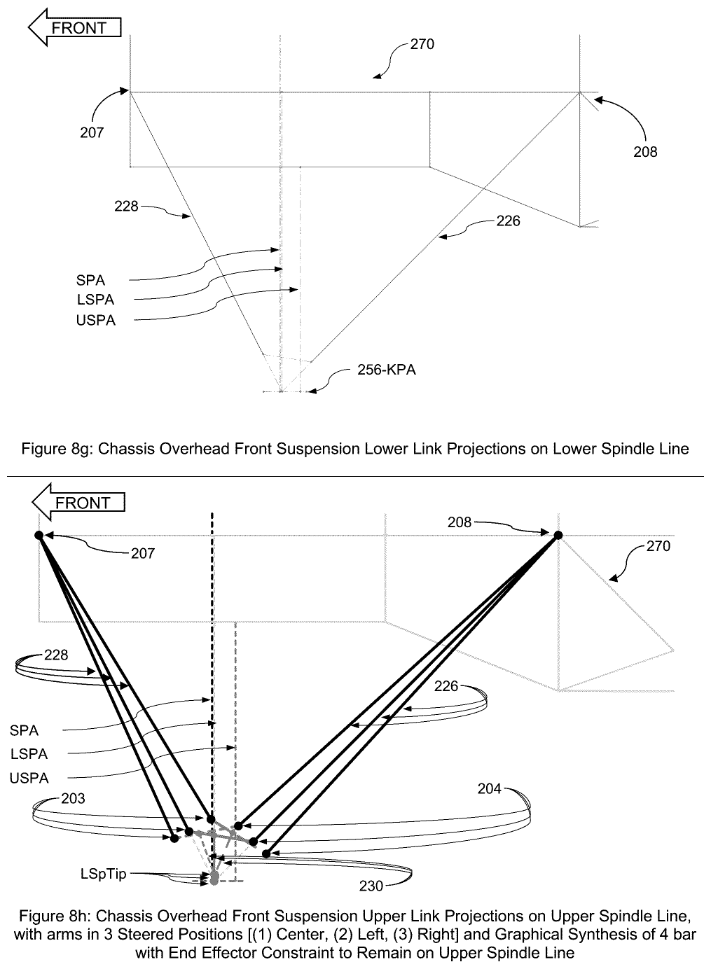

FIG. 8a illustrates an isometric view of a suspension system with an Upper Spindle Axis (USPA), a Lower Spindle Axis (LSPA), and the Initial Spindle Axis (SPA) projected out to the Kingpin Axis 256, and some static castor detailed by a non-zero Mechanical Trail. The Upper Spindle Axis (USPA) is shown as a horizontal line perpendicular to the upper inboard chassis pick up points connecting to the Kingpin Axis 256 and parallel to the Initial Spindle Axis (SPA). The Lower Spindle Axis (LSPA) is shown as a horizontal line perpendicular to the lower inboard chassis pick up points connecting to the Kingpin Axis 256 and parallel to the Initial Spindle Axis (SPA).

FIG. 8b illustrates an isometric view of the overhead design of the suspension system of FIG. 8a with preliminary upper and lower links drawn in the plane of the Upper Spindle Axis and Lower Spindle Axis, respectively. At this preliminary two dimensional stage of the design method, the suspension system includes upper links 222, 224 and lower links 226, 228. The front, upper link 222 is coupled to the chassis 270 at point 205 and would be coupled to the knuckle 230 at point 201. The back, upper link 224 is coupled to the chassis 270 at point 206 and is coupled to the knuckle 230 at point 202. The front, lower link 228 is coupled to the chassis 270 at point 207 and is coupled to the knuckle 230 at point 203. The back, lower link 226 is coupled to the chassis 270 at point 208 and is coupled to the knuckle 230 at point 204. As shown, projected lines along the upper links 222, 224 intersect at a point on the upper Spindle Axis (USPA) and Kingpin Axis to form an isosceles triangle. Projected lines along the lower links 226, 228 intersect at a point on the lower Spindle Axis (LSPA) and Kingpin Axis, and forms an isosceles triangle.

FIG. 8c illustrates a front view of the suspension system of FIG. 8a, and shows that the two-dimensional depictions of the upper and lower suspension, when viewed from above, are in two separate planes defined by the inboard chassis pick up points for the suspension.

FIG. 8d illustrates an overhead view of the two-dimensional depictions of FIG. 8b of the upper links 222, 224 and the lower links 226, 228 drawn with isosceles triangles on the Upper Spindle Axis (USPA) and the Lower Spindle Axis (LSPA) for a complete rendering of one initial position and set of lengths for those links, when viewed from above.

FIG. 8e illustrates an initial depiction of the upper suspension links 222, 224, shown in the plane of the Upper Spindle Axis (USPA).

FIG. 8f illustrates steering movement of the upper links 222, 224. In all three positions the spindle tip, at the wheel center point, is constrained to remain on the Upper Spindle Axis (USPA), to ensure zero movement of the tire contact patch at the ground during suspension travel and through steering travel. In the overhead view, keeping the wheel center on the Upper Spindle Axis minimizes the movement of the wheel center off of the Spindle Axis (SPA) when steering the tire about the Kingpin Axis 256 (or steer axis). Representing where the spindle tip would be in the two-dimensional overhead view are the points labeled USpTip. In all three positions, the spindle tip, at the wheel center point, is constrained to remain on the Upper Spindle Axis (USPA), to ensure zero movement of the tire contact patch at the ground during suspension travel and through steering travel. In addition, maintaining the isosceles triangles as discussed above minimizes or reduces to zero the change in instant kingpin angle when the suspension moves through steering or vertical travel. By maintaining a constant scrub radius during steering, external fore/aft loads can be decoupled from the steering effort.

FIG. 8g illustrates an initial depiction of the lower suspension links 226, 228, shown in the plane of the Lower Spindle Axis (LSPA).

FIG. 8h illustrates movement of the lower links 226, 228. In all three positions, the spindle tip, at the wheel center point, is constrained to remain on the Lower Spindle Axis (LSPA), to ensure zero movement of the tire contact patch at the ground during suspension travel and through steering travel. Keeping the wheel center on the Lower Spindle Axis minimizes the movement of the wheel center off of the Spindle Axis (SPA) when steering the tire about the Kingpin Axis 256 (or steer axis). Representing where the spindle tip would be in the two dimensional overhead view are the points labeled LSpTip. In addition, maintaining the isosceles triangles as discussed above minimizes or reduces to zero the change in instant kingpin angle when the suspension moves through steering or vertical travel. By maintaining a constant (or zero) scrub radius during steering, external fore/aft loads can be decoupled from the steering effort.

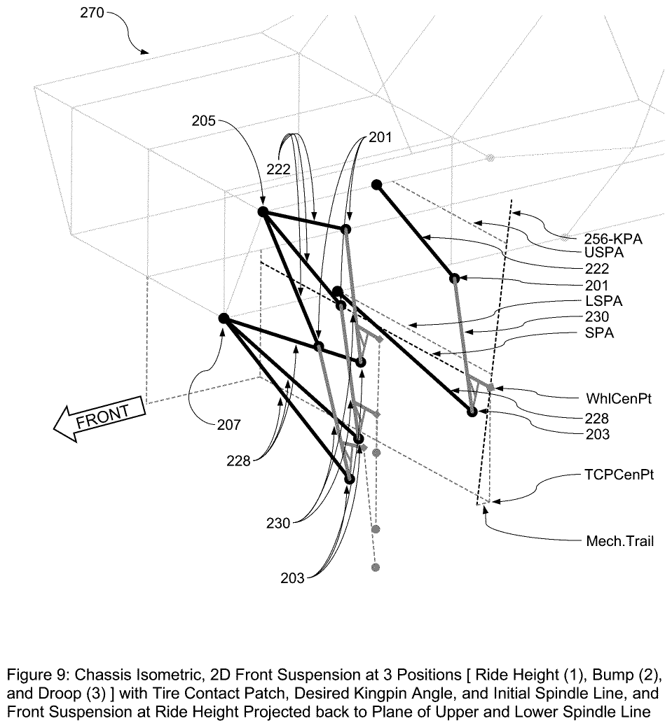

FIG. 9 illustrates another embodiment of a suspension system showing three different positions of the links 222, 228 with ride height (center) position projected back as a two-dimensional depiction to a plane of the spindle axis (tire center axis). The three front view positions are ride height, full bump and full droop with Tire Contact Patch, Desired Kingpin Angle, and Initial Spindle Axis.

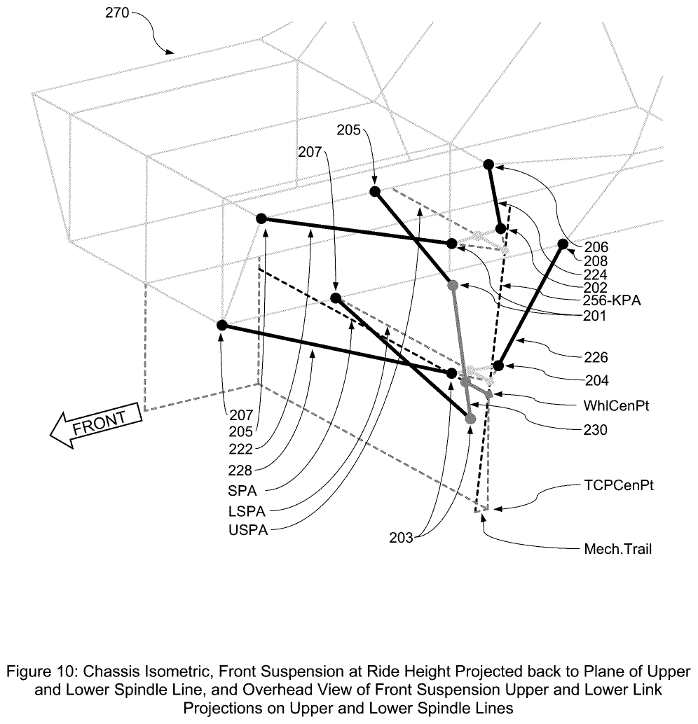

FIG. 10 illustrates the suspension system of FIG. 9 that includes the two upper links 222, 224 as drawn in FIG. 8f and the two lower links 226, 228 as drawn in FIG. 8h. The Figures further illustrates the two-dimensional suspension at Ride Height, as viewed from the front, as a two-dimensional depiction on the plane of spindle axis (tire center axis) and the upper and lower links viewed from above as two separate two-dimensional drawings in each separate semi-horizontal plane of suspension inboard pickup points.

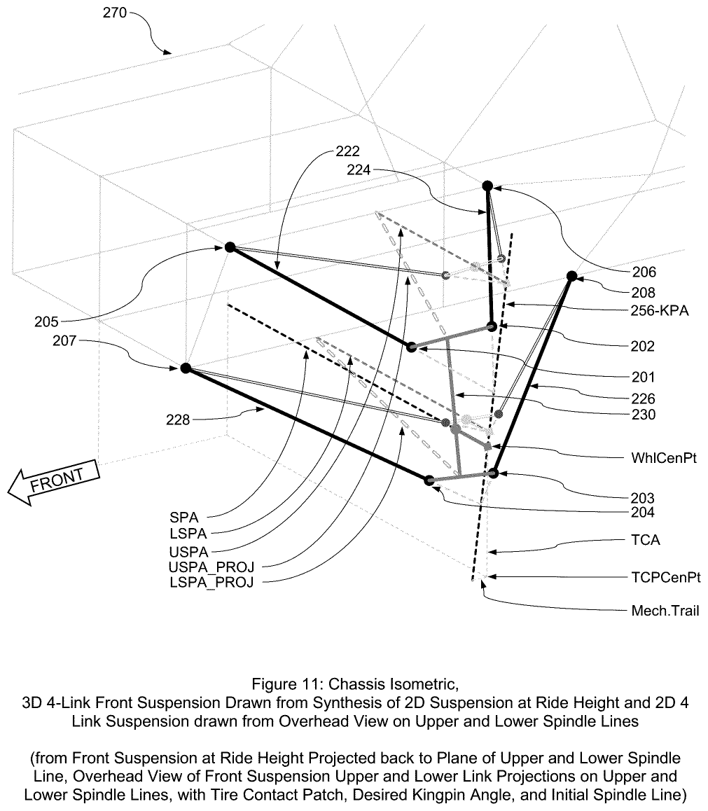

FIG. 11 illustrates for the first time the three dimensional positions of the four independent suspension links 222, 224, 226, 228 from the center position Front View 2D Suspension triad and the center positions upper and lower Overhead View 2D Suspension Triads (3 Position synthesis). FIG. 11 also shows a portion of the method best described as drawing four 3D lines that follow the overhead view lines when viewed from above and follow the suspension at ride height when viewed from the quasi-Vertical Transverse Plane. This step of the method is the synthesis of the 2D front view and two 2D overhead views, which dictate the positions of the links in the single 3D construction, as might be used on a vehicle.

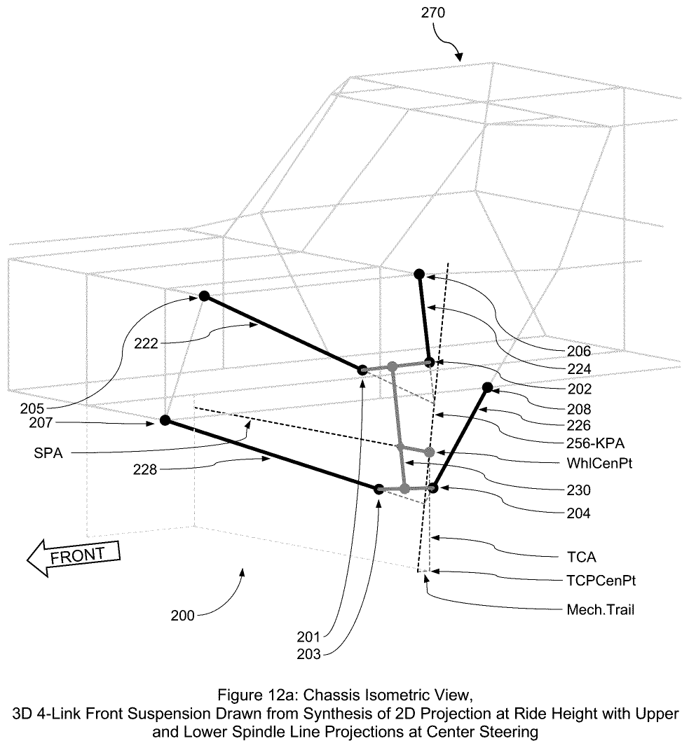

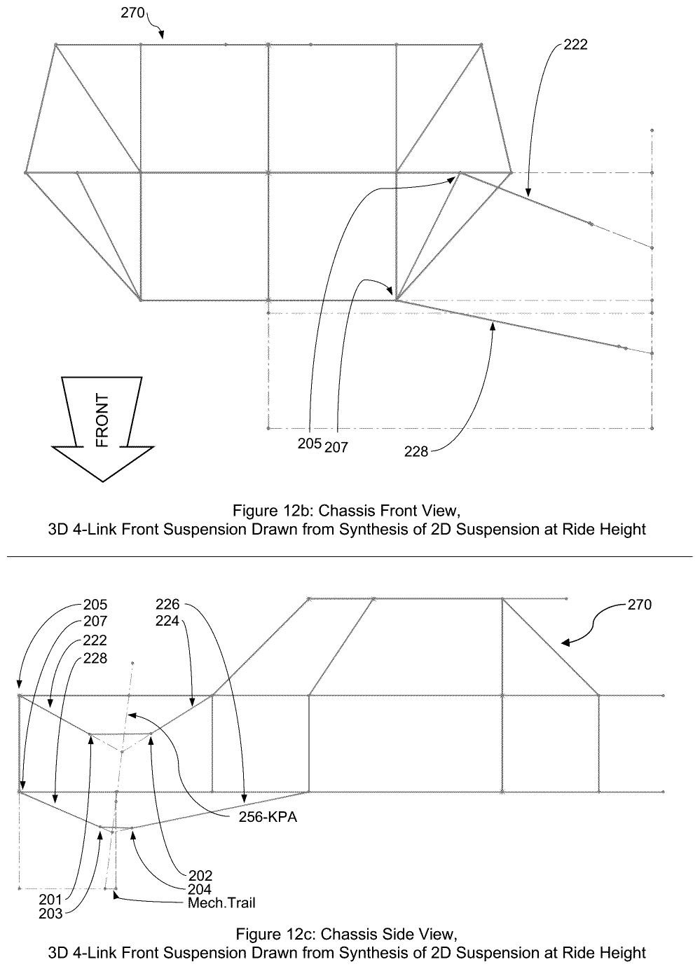

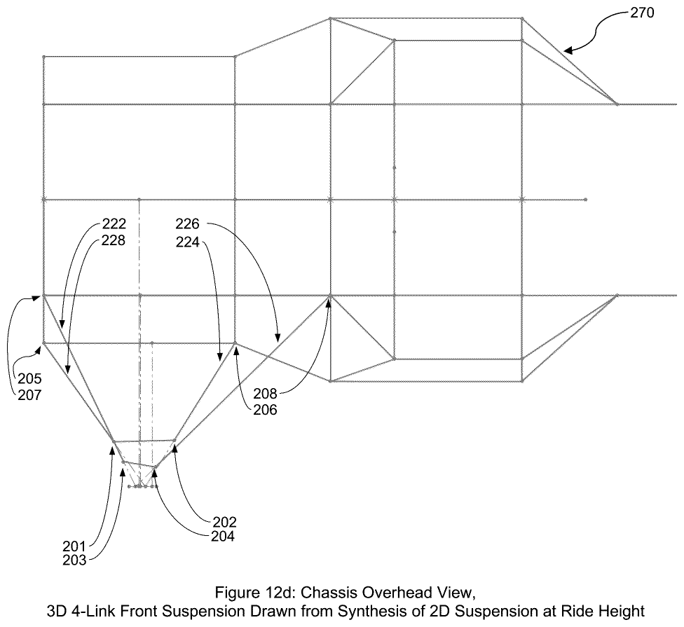

FIGS. 12a-12d illustrate multiple three-dimensional depictions of the four independent suspension links 222, 224, 226, 228. FIG. 12a presents an isometric view of the chassis 270 with the four independent suspension links 222, 224, 226, 228 designed from the previous synthesis of a two dimensional suspension at Ride Height.

FIG. 12b presents a front view of the chassis 270 with the four independent suspension links 222, 224, 226, 228 positioned from synthesis of a two dimensional suspension at Ride Height, while FIG. 12c presents a side view of the chassis 270 with the four independent suspension links 222, 224, 226, 228 positioned from synthesis of a two dimensional suspension at Ride Height. FIG. 12d presents an overhead view of the chassis 270 with the four independent suspension links 222, 224, 226, 228 positioned from synthesis of a two dimensional front plane suspension at Ride Height, and two separate two dimensional suspensions in the overhead view.

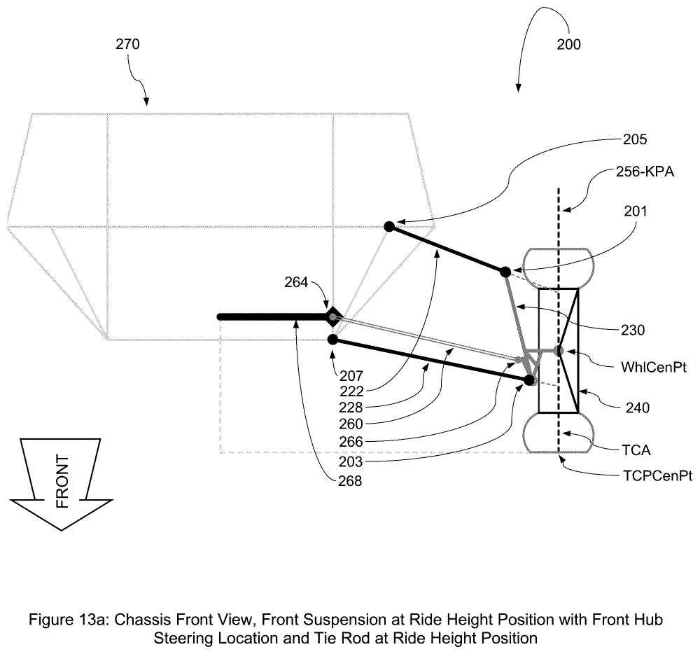

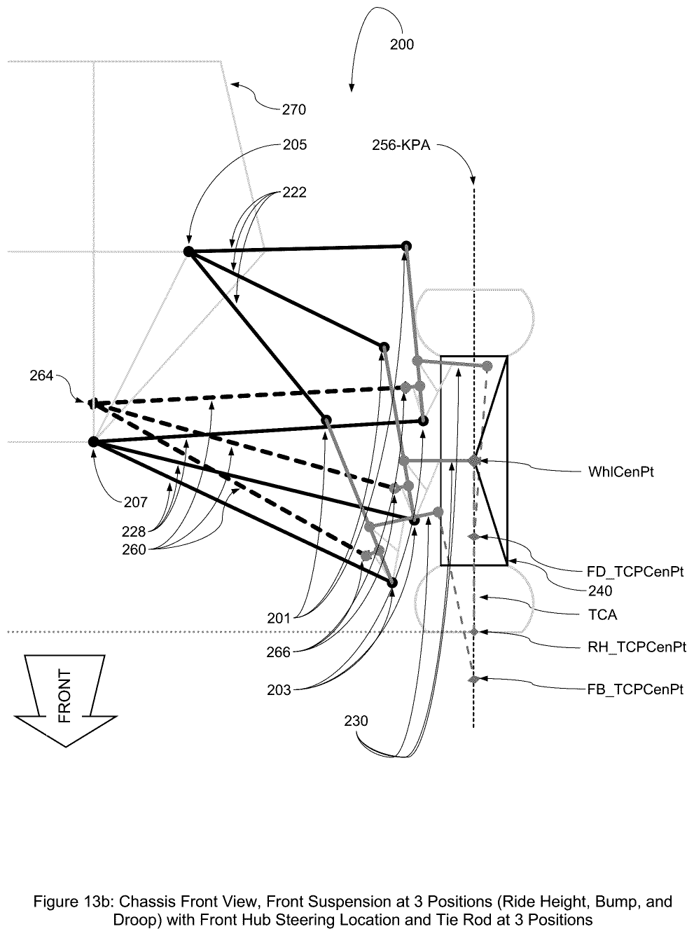

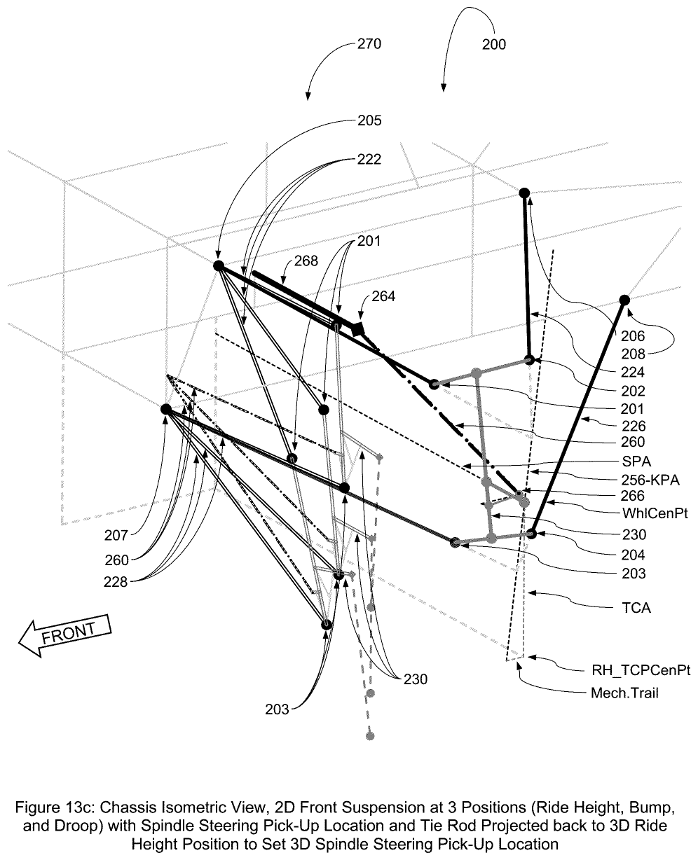

FIGS. 13a-13c illustrate a front view of the chassis 270 with the front suspension at three different positions (i.e., Ride Height, Full Bump, and Full Droop) with the addition of an exemplary steering system, and the Front Upright Steering Location on the outboard end. The tie rod 260 connects to a steering rack 268 within the chassis 270 at location 264 and the steering location connection point 266 on the upright 230.

FIG. 13b illustrates an isometric view of the chassis 270 with the front suspension links 222, 228 at three different positions (i.e., Ride Height, Full Bump, and Full Droop) with the spindle steering location and the tie rod 260 included in all three positions. By drawing three identical steering arms on all three vertical suspension positions to locate point 266 on the upright, from the front view, this geometrically constrains the system to have zero bump steer. When drawing three instances of the same length tie rod connection, from the upright at 226 to an inboard end of a steering system at 268, the tie rod length is graphically synthesized to result in the location of point 266. While the depiction shows the steering at straight ahead, the suspension system also minimizes, and/or brings to zero, bump steer in all other steering positions. The wheel (tire and rim) is shown only in the ride height position, but obviously is present an the other two positions as well.

FIG. 13c illustrates another isometric view which details how to select a steering arm position on the outboard wheel carrier, after first drawing the three-dimensional projection of this point on the plane of the initial Spindle Axis (SPA) and drawing some distance to the front or rear of the kingpin axis 256 to select the steering arm length, as shown in FIG. 13b. FIGS. 13a-13c collectively illustrate how the steering mechanism is configured after the suspension links are set, and constrained by those dimensions, to give zero bump steer during vertical suspension travel. Three equal length renderings of the tie rod 260 from a single inboard point 264 at the end of the steering rack converge on 3 separate uprights 230 at only a single locus, which defines the position of the tie rod connection to the upright, point 266, in the frontal view plane.

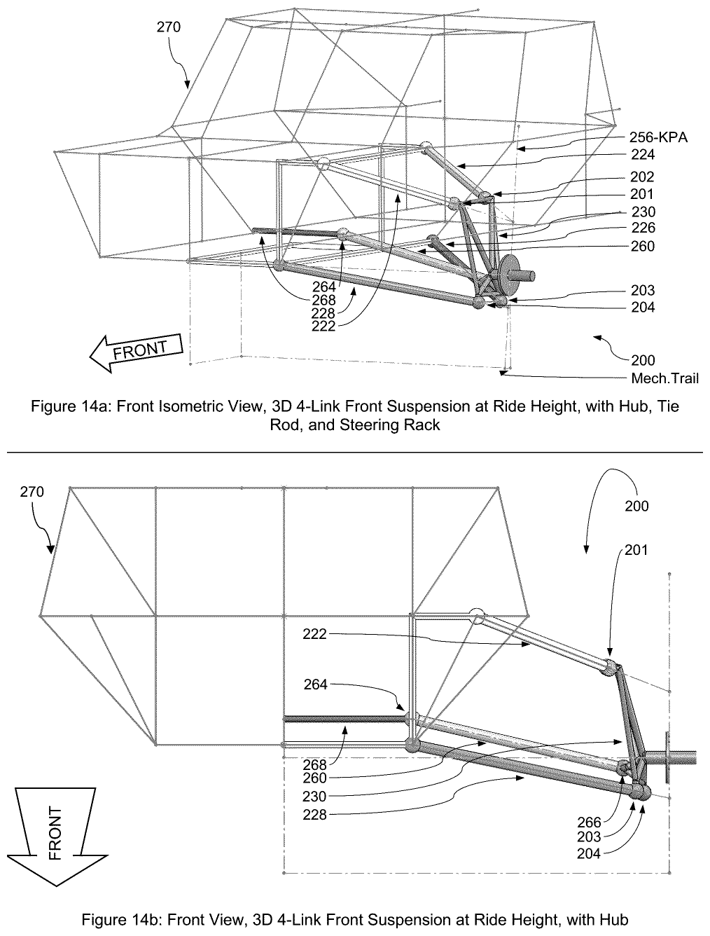

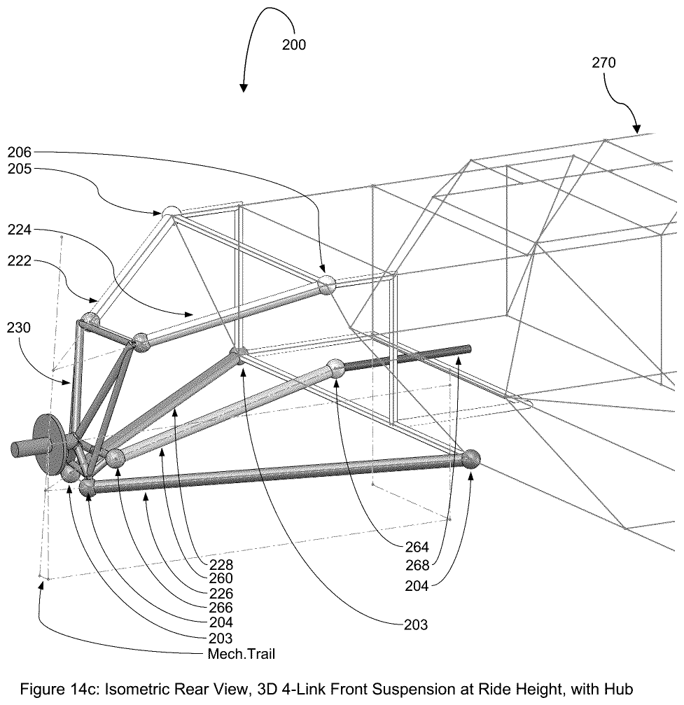

FIGS. 14a-14c are a rendering of an exemplary version of a three-dimensional suspension system utilizing the prior design method. The independent suspension links 222, 224, 226, 228 can each be coupled to the upright (or spindle or wheel carrier) at points 201, 202, 204, 203, respectively, in a ball joint configuration or multiple other suitable configuration. While one could conceivably connect any or all of the suspension links 222, 224, 226, 228 to the wheel carrier in single shear, a preferred method is to connect those joints using rod ends or Heim joints in double shear. The ball joints can be angled in the upright as desired to allow clearance during steering and suspension travel.

FIG. 14b is a front view of the suspension of FIG. 14a at Ride Height with hub, and FIG. 14c is an isometric rear view of the suspension of FIG. 14a at Ride Height with hub.

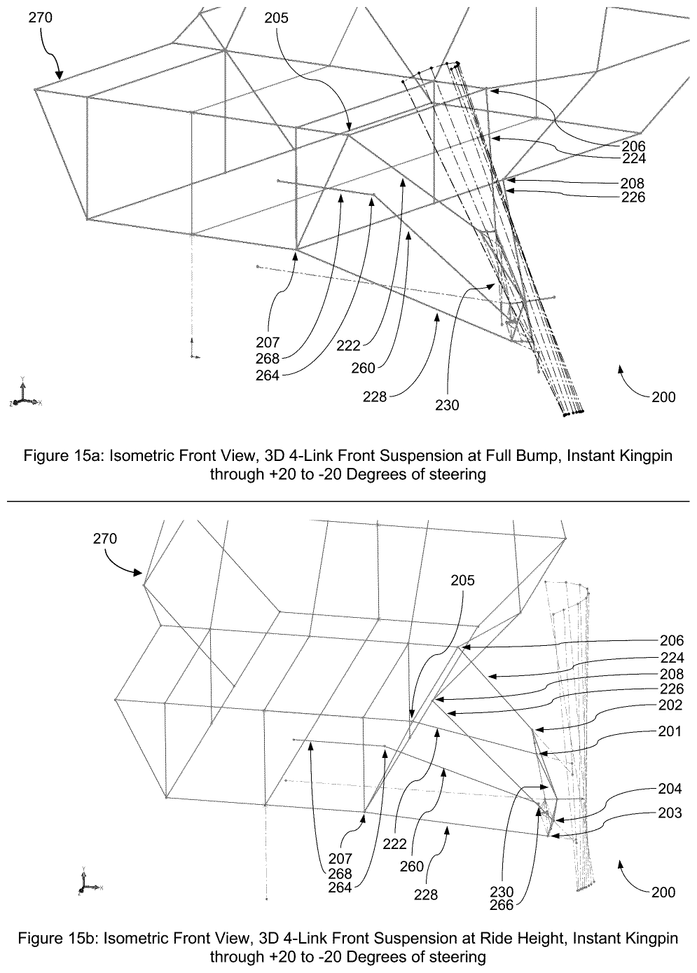

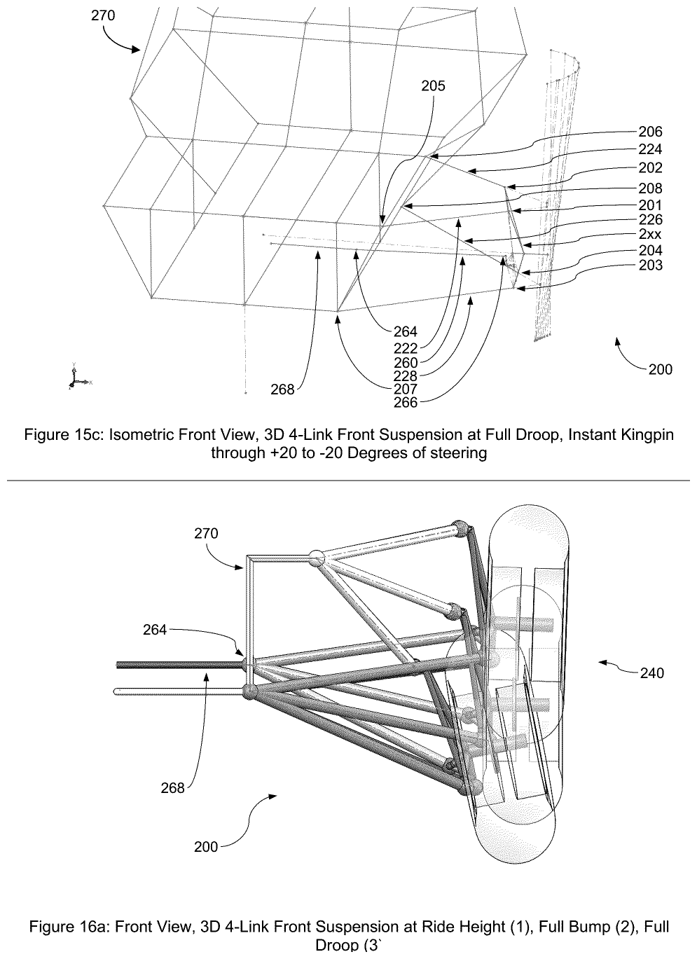

FIGS. 15a-15c are renderings of the swarm of instant centers of the kingpin angle through steering at an individual vertical suspension positions. While the suspension is pictured in one position, the multiple instant Kingpin Axis' were generated by sweeping the suspension through steering at a given vertical travel position.

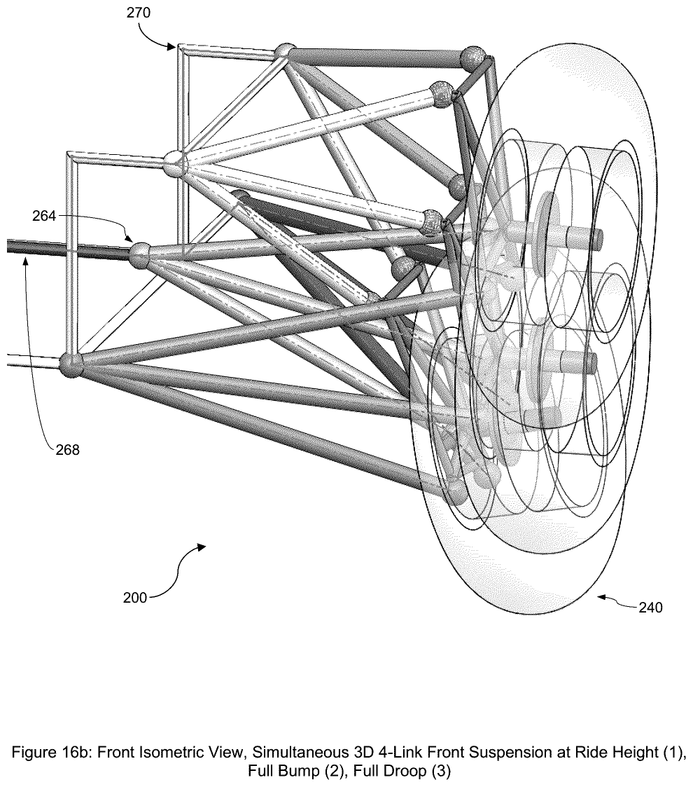

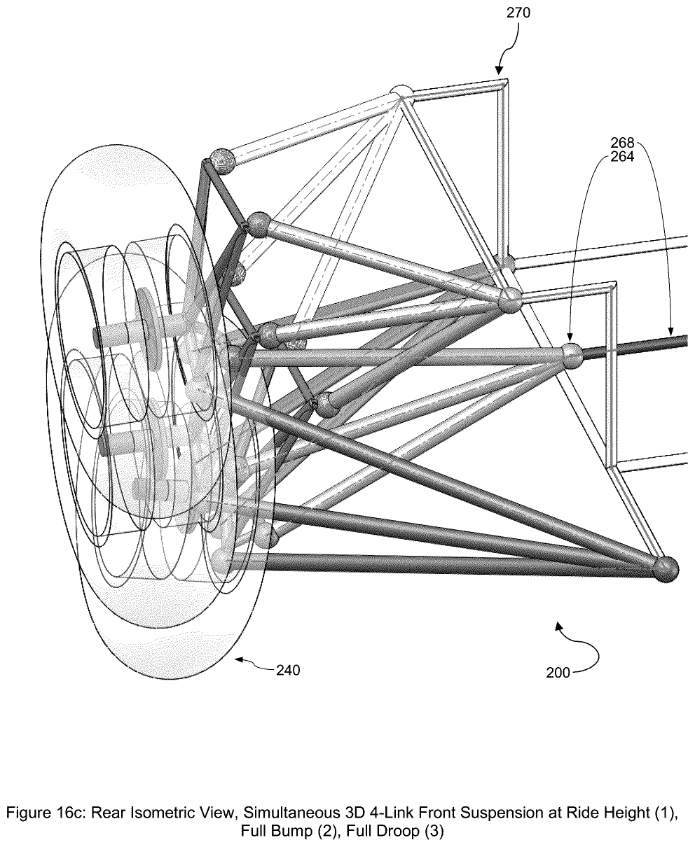

FIGS. 16a-16c present a rendering of an exemplary vehicle corner in three-dimensions with a tire, in three different positions, with the four link suspension system at Ride Height, at Full Bump, and at Full Droop.

Specifically, FIG. 16b depicts a front isometric view of the suspension system at Ride Height, at Full Bump, and at Full Droop, while FIG. 16c illustrates a rear isometric view of the suspension system at Ride Height, at Full Bump, and at Full Droop.

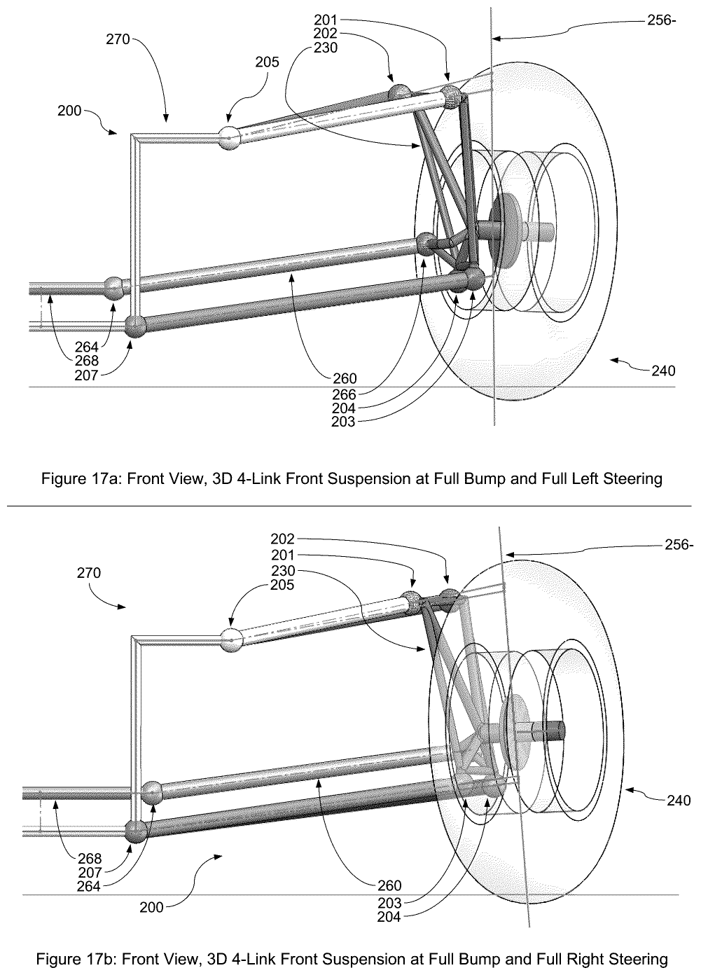

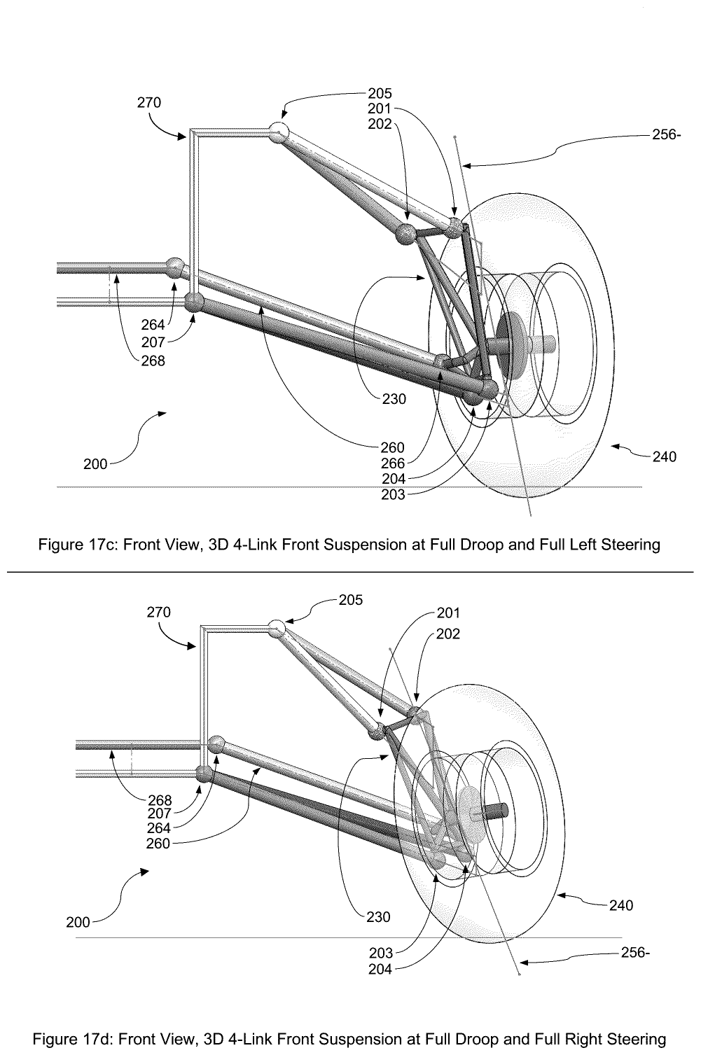

FIGS. 17a-17d present various renderings of the same exemplary vehicle corner with a tire and a ground plane, showing the Kingpin Axis intersection with the ground during steering and vertical wheel travel, which continuously exhibits the same distance to the tire contact patch center point during these articulations. FIG. 17b presents a front view of the suspension system at full bump and full right steering, and FIG. 17c a front view of the suspension system at full droop and full left steering.

FIG. 17d presents a front view of the suspension system at full droop and full right steering. The above discussion does not include the use of initial static camber, where the top of the wheel would be inclined toward the chassis in the initial, at rest, at ride height, and steered straight ahead, position. It is contemplated that one of ordinary skill in the art could adjust the angle of the kingpin axis to incline toward the chassis at the top, when viewed from the front, such as in FIG. 6a, to provide static camber.

While the vast majority of these methods disclosed in this patent describe how to create a vehicle suspension using multiple simultaneous iterations of a graphical method for four-bar linkage synthesis, Analytical methods to achieve the same end also exist. Analytical methods can be more practical when an analysis of the sequence of positions of the four-bar mechanism is desired. While such analytical methods can be done on paper, it is very common to use computer systems to write software that makes the analysis more adjustable and capable of running permutations. Most analytical methods will incorporate an initial vector layout and analysis, where a vector is described in terms of its component or origin, length, and direction along each coordinate axis. Even when vectors are used to describe the motion of a linkage, it is common to make a sketch of the linkage system so that naming conventions can be applied and so that vector directions can be referred to linkage orientation.

One such an Analytical Method for three position synthesis of four-bar design is described in Norton's “Design of Machinery, 2nd Ed”, starting on page 202. While the analytical method starts with three positions synthesis of a four-bar linkage, the method goes on to describe designing for a remote point on one of the four-bar linkages, which is an alternate method to constraining the remote end effector or coupler point (the suspension point of contact with the ground) shown in FIG. 6B. As well, while Norton details how to achieve the positioning in two-dimensional space, the inventive subject matter disclosed here-in requires the use of the same concepts in three-dimensional space.

It is likely one skilled in the art could conceive of a third method which involves using life size prototype pieces of suspension members to gradually optimize an equivalent suspension system through trial and error. Such an attempt might involve laying out a frontal plane system on a large flat surface, such as a welding table, and cycling the prototype suspension through vertical travel. As well, one could fabricate an adjustable set of links to simulate an overhead view of such a mechanical suspension. However, as these methods would result in an similar or identical design as the methods laid out here-in using a graphical synthesis, or an analytical synthesis, those methods to achieve the same result are here-by incorporated.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

In some embodiments, the numbers expressing quantities of ingredients, properties such as concentration, reaction conditions, and so forth, used to describe and claim certain embodiments of the invention are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the invention are approximations, the numerical values set forth in the specific examples are reported as precisely as practicable. The numerical values presented in some embodiments of the invention may contain certain errors necessarily resulting from the standard deviation found in their respective testing measurements.

Unless the context dictates the contrary, all ranges set forth herein should be interpreted as being inclusive of their endpoints and open-ended ranges should be interpreted to include only commercially practical values. Similarly, all lists of values should be considered as inclusive of intermediate values unless the context indicates the contrary.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

The recitation of ranges of values herein is merely intended to serve as a shorthand method of referring individually to each separate value falling within the range. Unless otherwise indicated herein, each individual value with a range is incorporated into the specification as if it were individually recited herein. All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

It should be apparent to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. A method for configuring a suspension system for a vehicle having a ride height, a track width, a wheel width and a wheel height, such that the suspension system has zero scrub radius and zero bump steer, comprising:
generating an initial Spindle Axis from a center of a wheel of the vehicle to a chassis of the vehicle, wherein the chassis comprises a set of front inboard pickup points and a set of rear inboard pickup points;
defining a vertical transverse or quasi-vertical transverse plane parallel to the initial Spindle Axis which intersects both of either the front inboard pickup points or the rear inboard pickup points;
selecting a point on the vertical transverse or quasi-vertical transverse plane that is coincident with a tire ground contact center point;
placing a wheel and tire on the vertical transverse or quasi-vertical transverse plane based on the wheel height and the track width at ride height;
placing an upright on the vertical transverse or quasi-vertical transverse plane and defining an initial position of those points;
generating an initial centerline position of a first link, a second link, a third link, and a fourth link, wherein each of the first link, a second link, a third link, and a fourth link couples the upright to the chassis;
drawing two more positions of the vehicle suspension on that plane in a graphical four-bar linkage synthesis, most likely chosen to be full bump and full droop;
constraining the three renditions of the upper arms, lower arms, and upright to have the same length, and an identical line from the three spindle center to have the same length from the vehicle centerline demonstrating no change in track width;
adjusting the 4 independent variables or the 9 lengths drawn to achieve a suspension that fits all other constraints such as packaging within the wheel and tire combo or brake caliper and rotor clearance;
in 3D space drawing the Kingpin Axis, through the initial Spindle Axis, with two chosen angles to the Horizontal plane to exhibit initial camber and castor, and drawing the castor line from the intersection of the ground plane and the kingpin line, to the tire center ground contact point;
drawing the Upper Spindle Axis, comprised of a horizontal line perpendicular to the Upper inboard chassis pick up points connecting to the kingpin line and parallel to the Initial Spindle Axis;
drawing the Lower Spindle Axis, comprised of a horizontal line perpendicular to the Lower inboard chassis pick up points connecting to the Kingpin Axis and parallel to the Initial Spindle Axis;
drawing the overhead view of the upper suspension links between the inboard chassis pickup points and toward the intersection point of the Upper Spindle Axis and the Kingpin Axis, with the outboard ends of the links stopping short of the Kingpin Axis by two equal length lines;
drawing the overhead view of the lower suspension links between the inboard chassis pickup points and toward the intersection point of the Lower Spindle Axis and the Kingpin Axis, with the outboard ends of the links stopping short of the Kingpin Axis by two equal length lines;
drawing four 3D lines that following the overhead view lines when viewed from above and follow the suspension at ride height when viewed from the quasi-Vertical Transverse Plane;
returning to the quasi-Vertical Transverse Plane and drawing 3 identical steering arms on all three positions the front view of the upright, and geometrically constraining the system to have zero bump steer by drawing three instances of the same tie rod connection to inboard end of a steering system; and
selecting the steering arm length on the outboard wheel carrier by drawing the 3D projection of this point on the plane of the initial Spindle Axis drawing some distance to the front or rear of the kingpin line to select the steering arm length.

2. The suspension system of claim 1, where a traditional A-arm suspension member with dual inboard connections and a single outboard connection is used in the upper position to attach the wheel upright to the vehicle chassis.

3. The suspension system of claim 1, where a traditional A-arm suspension member with dual inboard connections and a single outboard connection is used in the lower position to attach the wheel upright to the vehicle chassis.

4. The suspension system of claim 1, where analytical methods are used to synthesize positions of four-bar linkages in the place of the disclosed graphical methods.

5. The suspension system of claim 1, where prototyping and fabrications methods are used to synthesize positions of four-bar linkages in the place of the disclosed graphical methods.
